(19) United States
(12) Patent Application Publication
(10) Pub. No.: US 2021/0074660 A1
(43) Pub. Date: Mar. 11, 2021

(54) SEMICONDUCTOR PACKAGE INCLUDING CONDUCTIVE BUMPS AND METHOD OF MANUFACTURING THE SEMICONDUCTOR PACKAGE

(71) Applicant: SAMSUNG ELECTRONICS CO., LTD., Suwon-si (KR)

(72) Inventor: Seyong Lee, Seoul (KR)

(21) Appl. No.: 16/864,783

(22) Filed: May 1, 2020

(30) Foreign Application Priority Data
Sep. 11, 2019 (KR) 10-2019-0112510

(51) Int. Cl. H01L 23/00; H01L 23/31; H01L 25/065

(52) U.S. Cl. CPC H01L 24/13; H01L 23/3178; H01L 24/73; H01L 24/29; H01L 24/05; H01L 25/0657

(57) ABSTRACT

A semiconductor package includes a first semiconductor chip including a first through electrode. A second semiconductor chip is stacked on the first semiconductor chip. The second semiconductor chip includes a second through electrode. A plurality of conductive bumps are interposed between the first semiconductor chip and the second semiconductor chip. The conductive bumps electrically connect the first and second through electrodes to each other. A filling support layer at least partially covers a first surface of the second semiconductor chip facing the first semiconductor chip and at least partially fills spaces between the conductive bumps. An adhesive layer is disposed on the filling support layer at least partially filling the spaces between the conductive bumps and adhering the first and second semiconductor chips to each other.

### CROSS-REFERENCE TO RELATED APPLICATION

This application claims priority under 35 U.S.C. § 119 to Korean Patent Application No. 10-2019-0112510, filed on Sep. 11, 2019 in the Korean. Intellectual Property Office (KIPO), the contents of which are herein incorporated by reference in their entirety.

### Technical Field

The present disclosure relates to a semiconductor package and, more specifically, a semiconductor package including conductive bumps and a method of manufacturing the same.

### Discussion of the Related Art

In manufacturing a multi-chip package including semiconductor chips that are electrically connected to each other by through electrodes, after a wafer is supported on a carrier substrate using a substrate support system, a backside of the wafer may be winded to reduce the thickness of the wafer. However, because the wafer can be warped or damaged during the grinding process, there may be a limit to how much the wafer may be safely reducing in thickness.

### SUMMARY

According to exemplary embodiments of the present disclosure, a semiconductor package includes a first semiconductor chip including a first through electrode. A second semiconductor chip is stacked on the first semiconductor chip and the second semiconductor chip includes a second through electrode. A plurality of conductive bumps are interposed between the first semiconductor chip and the second semiconductor chip and electrically connect the first and second through electrodes. A filling support layer covers a first surface of the second semiconductor chip facing the first semiconductor chip and fills spaces between the conductive bumps. An adhesive layer is disposed on the filling support layer and fills the spaces between the conductive bumps and adheres the first and second semiconductor chips to each other.

According to exemplary embodiments of the present disclosure, a semiconductor package includes a first semiconductor chip including a first substrate having a first surface and a second surface opposite to the first surface. A first bonding pad is disposed on the first surface. A first through electrode penetrates through the first substrate and is electrically connected to the first bonding pad. A second semiconductor chip is stacked on the second surface of the first semiconductor chip and includes a second substrate having a third surface and a fourth surface opposite to the third surface. A third bonding pad is disposed on the third surface. A second through electrode penetrates through the second substrate and is electrically connected to the third bonding pad. A plurality of conductive bumps are interposed between the first semiconductor chip and the second semiconductor chip and electrically connect the first and second through electrodes to each other. A gap filling material layer is provided between the first semiconductor chip and the second semiconductor chip to fill spaces between the conductive bumps. The gap filling material layer includes a filling support layer of a first material at least partially covering a front side of the second semiconductor chip facing the first semiconductor chip and an adhesive layer of a second material adhering to the filling support layer.

According to exemplary embodiments of the present disclosure, a semiconductor package includes a package substrate. A first semiconductor chip is stacked on the package substrate and includes a first substrate having a first surface and a second surface opposite to the first surface. First bonding pads are disposed on the first surface. A first through electrode penetrates through the first substrate and is electrically connected to the first bonding pad. A plurality of conductive bumps arranged between substrate pads of the package substrate and the first bonding pads of the first semiconductor chip respectively. A filling support layer is coated on the first surface of the first semiconductor chip and covers a side surface of the conductive bump. An adhesive layer is disposed on the filling support layer at least partially covering the side surface of the conductive bump and adhering the package substrate and the first semiconductor chip.

According to exemplary embodiments of the present disclosure, in a method of manufacturing a semiconductor package, a first substrate having first bonding pads on a first surface thereof is provided. Bumps are formed on the first bonding pads of the first substrate respectively. A filling support layer is formed on the first surface of the first substrate to fill spaces between the bumps. An adhesive layer is coated on the filling support layer. A second surface of the first substrate opposite to the first surface is grinded. The first substrate is adhered to a second substrate using the adhesive layer.

According to exemplary embodiments of the present disclosure, a semiconductor package may include at least two first and second semiconductor chips sequentially stacked on a package substrate. The first and second semiconductor chips may be stacked via first and second conductive bumps. Gap filling material layers having a double layer structure of different materials may be filled between the package substrate and the first semiconductor chip and between the first semiconductor chip and the second semiconductor chip respectively. The gap filling material layers may completely fill the spaces between neighboring bumps of the first conductive bumps and the spaces between neighboring bumps a the second conductive bumps, respectively. Alternatively, the gap filling material layers may partially fill these spaces. The gap filling material layer may include a filling support layer and an adhesive layer.

The filling support layers may fill the spaces between the first conductive bumps and the spaces between the second conductive bumps respectively, and accordingly, a backside of a wafer level chip may be grinded such that the first and second semiconductor chips are relatively thin. Further, as the first and second conductive bumps are relatively thin due to the filling support layers a relatively thin semiconductor package may be obtained.

### BRIEF DESCRIPTION OF THE DRAWINGS

Exemplary embodiments of the present disclosure and many of the attendant aspects thereof will be more clearly understood from the following detailed description taken in conjunction with the accompanying drawings, wherein:

FIG. 1 is a cross-sectional view illustrating a semiconductor package in accordance with exemplary embodiments of the present disclosure;

FIG. 2 is an enlarged cross-sectional view illustrating portion A in FIG. 1;

FIG. 3 is an enlarged cross-sectional view illustrating portion B in FIG. 1;

FIG. 4 is an enlarged cross-sectional view illustrating portion C in FIG. 1;

FIGS. 5 to 26 are cross-sectional views illustrating a method of manufacturing a semiconductor package according to exemplary embodiments of the present disclosure;

FIG. 27A is a cross-sectional view illustrating a first semiconductor chip stacked on a mounting substrate in accordance with a comparative embodiment;

FIG. 27B is a cross-sectional view illustrating a first semiconductor chip stacked on a mourning substrate in accordance with exemplary embodiments of the present disclosure; and

FIG. 28 is a cross-sectional view illustrating a semiconductor package in accordance with exemplary embodiments of the present disclosure.

### DETAILED DESCRIPTION OF EXAMPLE EMBODIMENTS

Hereinafter, exemplary embodiments of the present disclosure will be explained in detail with reference to the accompanying drawings.

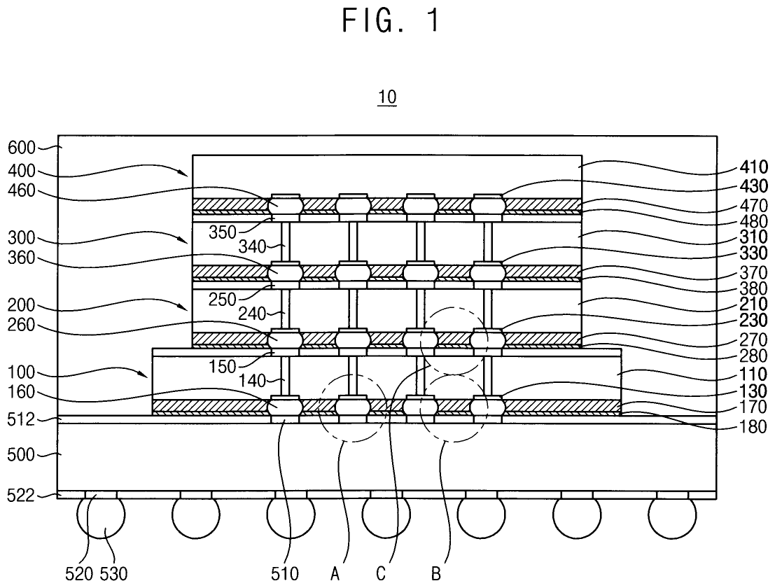

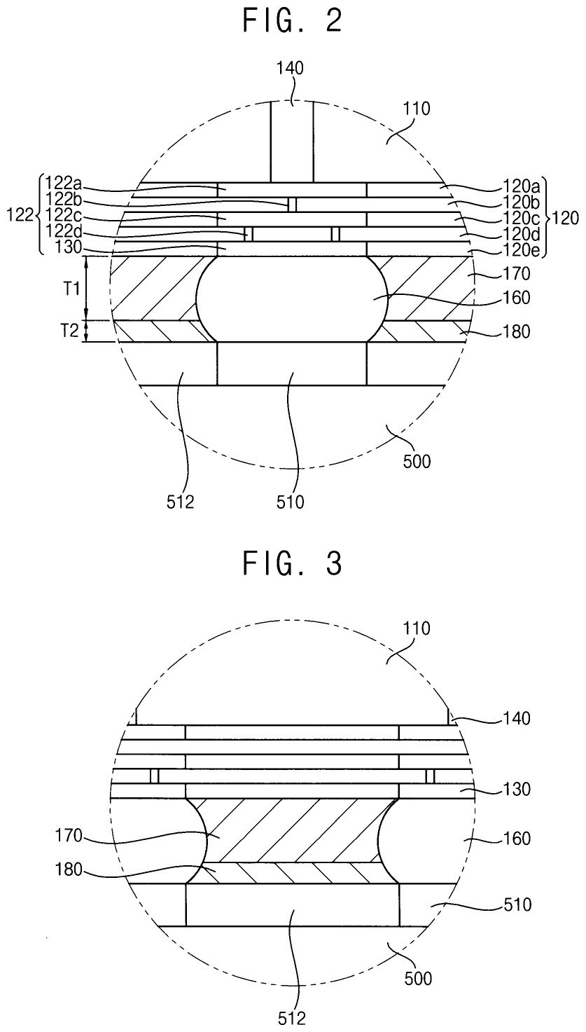

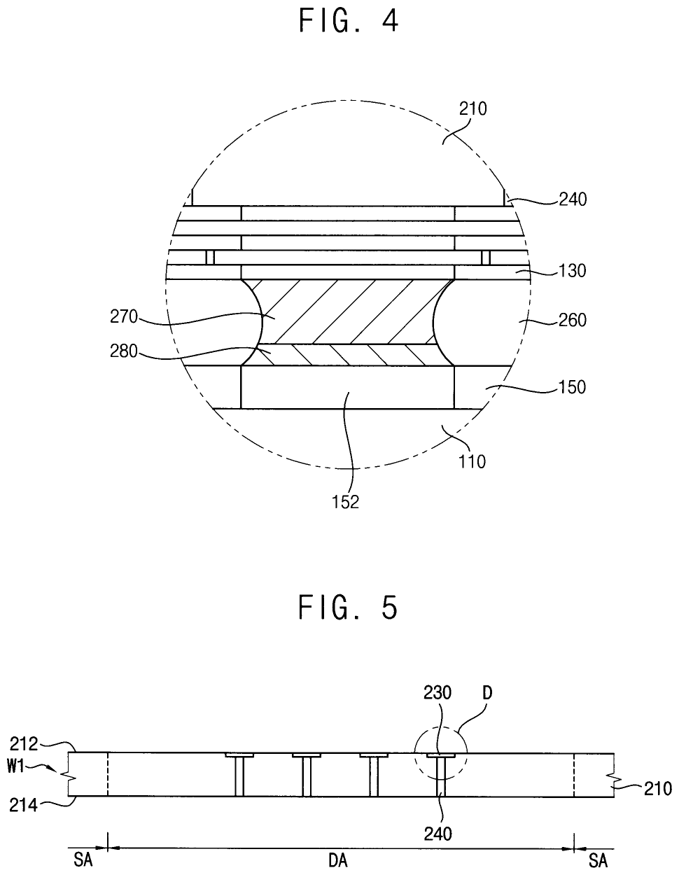

FIG. 1 is a cross-sectional view illustrating a semiconductor package in accordance with exemplary embodiments of the present disclosure. FIG. 2 is an enlarged cross-sectional view illustrating portion A in FIG. 1. FIG. 3 is an enlarged cross-sectional view illustrating portion B in FIG. 1. FIG. 4 is an enlarged cross-sectional view illustrating portion C in FIG. 1.

Referring to FIGS. 1 to 4, a semiconductor package 10 may include stacked semiconductor chips. The semiconductor package 10 may include a package substrate 500, first to fourth semiconductor chips 100, 200, 300, 400 and a molding member 600. Additionally, the semiconductor package 10 may further include first to fourth conductive bumps 160, 260, 360, 460 and outer connection members 530 electrical connecting the package substrate 500 and the first to fourth semiconductor chips 100, 200, 300, 400.

The package substrate 500 may include a printed circuit board (PCB) including circuit patterns disposed therein/thereon. A first insulation layer pattern 512 may be provided on an upper surface of the package substrate 500 to expose substrate pads 510. A second insulation layer pattern 522 may be provided on a lower surface of the package substrate 500 to expose outer connection pads 520. The outer connection members 530 such as solder balls may be provided on the outer connection pads 530.

A plurality of the semiconductor chips may be stacked on the upper surface of the package substrate 500. In this embodiment, the first to fourth semiconductor chips 100, 200, 300, 400 may be substantially the same as or similar to each other. Thus, same or like reference numerals will be used to refer to the same or like elements and to the extent that a detailed description of some elements is omitted, it may be assumed that these elements are at least similar to corresponding elements that have been described elsewhere in the specification.

The first to fourth semiconductor chips 100, 200, 300, 400 may be stacked on the package substrate 500. In this embodiment, the semiconductor package is depicted as a multi-chip package including four stacked semiconductor chips 100, 200. 300, 400. However, the semiconductor package may have a different number of semiconductor chips stacked thereon, such as two stacked semiconductor chips, three stacked semiconductor chips, or more than four stacked semiconductor chips.

For example, the semiconductor package 10 may include a HBM (High Bandwidth Memory) device. The semiconductor package 10 may include the first semiconductor chip 100 as a buffer die and the second to fourth, semiconductor chips 200, 300, 400 as memory dies sequentially stacked on the first semiconductor chip 100. The first to fourth semiconductor chips 100, 200, 300, 400 may be electrically connected to each other by through silicon vias (TSVs).

The first semiconductor chip 100 may be mounted on the package substrate 500 via first conductive bumps 160. The first semiconductor chip 100 may include a first substrate 110, an insulation interlayer 120, a first bonding pad 130, a first through electrode 140, and a second bonding pad 150.

The first substrate 110 may include a first surface and a second surface opposite to each other. The first surface may be an active surface, and the second surface may be a non-active surface. Various circuit patterns may be provided in the first surface of the first substrate 110. For example, the first substrate 110 may be a single crystalline silicon substrate. The circuit patterns may include a transistor, a diode, etc. The circuit patterns may constitute circuit elements. Accordingly, the first semiconductor chip 100 may be a semiconductor device including a plurality of the circuit elements formed therein.

The insulation interlayer 120 may be provided on the first surface of the first substrate 110. The insulation interlayer 120 may include a plurality of insulation layers 120a, 120b, 120c, 120d, 120e and a wiring 122 in the insulation layers. The first bonding pad 130 may be provided in the outermost insulation layer 120e of the insulation interlayer 120. The circuit patterns may be electrically connected to the first bonding pad 130 by the wirings.

For example, the wiring 122 may include a first metal wiring 122a, a first contact 122b, a second metal wiring 122d and a third metal wiring 130 respectively provided in the insulation layers 120a, 120b, 120c, 120d, 120e. At least a portion of the third metal wiring 130 may serve as the first bonding pad 130 and/or as a landing pad. Thus, both the third metal wiring and the first bonding pad may be represented herein by numeral 130.

The insulation interlayer 120 including two metal wiring layers 122a, 122c may be exemplarily illustrated, and it is to be understood that there may be fewer or more than two metal wiring layers in use. For example, the insulation interlayer 120 may be a BEOL (back end of line) metal wiring layer and may include three or more metal wiring layers.

The first through electrode 140 may extend from the second surface of the first substrate 110 to the first surface to penetrate through the first substrate 110. An end portion of the first through electrode 140 may make contact with the first metal wiring 122a of the insulation interlayer 120. However, the present invention may use alternative newts of interconnection, for example, the first through electrode 140 may penetrate through the insulation interlayer 120 to make contact with the first bonding pad 130.

An insulation layer 152 having the second bonding pad 150 may be provided on the second surface of the first substrate 110. The second bonding pad 150 may make contact with another end portion of the first through electrode 140.

In exemplary embodiments of the present disclosure, the first semiconductor chip 100 may be mounted on the package substrate 500 via the first conductive bumps 160. The first semiconductor chip 100 may be arranged on the package substrate 500 such that the first bonding pad 130 of the first semiconductor chip 100 faces toward the substrate pad 510 of the package substrate 500.

The first conductive bump 160 may be interposed between the package substrate 500 and the first semiconductor chip 100. The first conductive bump 160 may electrically connect the substrate pad 510 of the package substrate 500 and the first bonding pad 130 of the first semiconductor chip 100 to each other.

In exemplary embodiments of the present disclosure, a gap filling material layer having a double layer structure of different materials may be provided between the package substrate 500 and the first semiconductor chip 100. The gap filling material layer may be provided to completely fill spaces between neighboring bumps of the first conductive bumps 160. Alternatively, the gap filling material layer may partially fill these spaces. The gap filling material layer may include a filling support layer 170 and an adhesive layer 180.

The filling support layer 170 may be coated on a front side of the first semiconductor chip 100 facing the package substrate 500 to at least partially cover side surfaces of the first conductive bumps 160. The filling support layer 170 may cover side surfaces of a lower portion and a middle portion of the first conductive bump 160. A portion of an upper portion of the first conductive bump 160 may protrude from the filling support layer 170.

The filling support layer 170 may include an insulation material capable of preventing warpage of a wafer during a wafer backside grinding process. The filling support layer 170 may have a thermal expansion coefficient that is the same as or similar to that of the material of the first substrate 110, for example, silicon. For example, the filling support layer 170 may include a polymer material such as epoxy resin, photosensitive polyimide, etc.

The adhesive layer 180 may be provided on the filling support layer 170 to fill spaces between the first conductive bumps 160. The adhesive layer 180 may at least partially cover a side surface of the upper portion of the first conductive bump 160 protruding from the filling support layer 170.

For example, the adhesive layer 180 may include a non-conductive film (NCF). A solder bump on the first bonding pad 130 may be reflowed by thermal compression of a chip bonding apparatus to form the first conductive bump 160 and the first semiconductor chip 100 may be adhered on the package substrate 500 by the adhesive layer 180.

The filling support layer 170 may have a first thickness T1, and the adhesive layer 180 may have a second thickness T2 that is less than the first thickness T1. For example, the filling support layer 170 may have a thickness of 50% to 90% of a total thickness of the first conductive bump 160.

The second semiconductor chip 200 may be mounted on the first semiconductor chip 100 via second conductive bumps 260. Similarly to the first semiconductor chip 100, the second semiconductor chip 200 may include a second substrate 210, an insulation interlayer, a first bonding pad 230, a second through electrode 240, and a second bonding pad 250.

The second semiconductor chip 200 may be arranged on the first semiconductor chip 100 such that the first bonding pad 230 of the second semiconductor chip 200 faces toward the second bonding pad 150 of the first semiconductor chip 100.

The second conductive bump 260 may be interposed between the first semiconductor chip 100 and the second semiconductor chip 200. The second conductive bump 260 may electrically connect the second bonding pad 150 of the first semiconductor chip 100 and the first bonding pad 230 of the second semiconductor chip 200 to each other.

In exemplary embodiments of the present disclosure, a gap filling material layer haying a double layer structure of different materials may be provided between the first semiconductor chip 100 and the second semiconductor chip 200. The gap filling material layer may be provided to completely fill spaces between neighboring conductive bumps of the second conductive bumps 260. Alternatively, the gap filling material layer may partially fill the spaces between neighboring bumps of the second conductive bumps 260. The gap filling material layer may include a filling support layer 270 and an adhesive layer 280.

The filling support layer 270 may be coated on a front side of the second semiconductor chip 200 that is facing the first semiconductor chip 100 so as to at least partially cover side surfaces of the second conductive bumps 260. The filling support layer 270 may cover side surfaces of a lower portion and a middle portion of the second conductive bump 260. A portion of an upper portion of the second conductive bump 260 may protrude from the filling support layer 270.

The adhesive layer 280 may be provided on the filling support layer 270 to fill spaces between neighboring bumps of the second conductive bumps 260. The adhesive layer 280 may cover a side surface of the upper portion of the second conductive bump 260 protruding from the filling support layer 270. For example, the adhesive layer 280 may include a non-conductive film (NCF).

The filling support layer 270 may have a first thickness, and the adhesive layer 280 may have a second thickness that is less than the first thickness. For example, the filling support layer 270 may have a thickness of 50% to 90% of a total thickness of the second conductive bump 260.

The third semiconductor chip 300 may be mounted on the second semiconductor chip 200 via third conductive bumps 360. Similarly to the first and second semiconductor chips 100, 200, the third semiconductor chip 300 may include a third substrate 310, an insulation interlayer, a first bonding pad 330, a third through electrode 340, and a second bonding pad 350.

The third semiconductor chip 300 may be arranged on the second semiconductor chip 200 such that the first bonding pad 330 of the third semiconductor chip 300 faces toward the second bonding pad 250 of the second semiconductor chip 200.

The third conductive bump 360 may be interposed between the second semiconductor chip 200 and the third semiconductor chip 300. The third conductive bump 360 may electrically connect the second bonding pad 250 of the second semiconductor chip 200 and the first bonding pad 330 of the third semiconductor chip 300 to each other.

In exemplary embodiments of the present disclosure, a gap filling material layer having a double layer structure of different materials may be provided between the second semiconductor chip 200 and the third semiconductor chip 300. The gap filling material layer may be provided to completely fill spaces between neighboring bumps of the third conductive bumps 360. Alternatively, the gap filling material layer may partially fill spaces between neighboring bumps of the third conductive bumps. The gap filling material layer may include a filling support layer 370 and an adhesive layer 380.

The filling support layer 370 may be coated on a front side of the third semiconductor chip 300 facing the second semiconductor chip 200 to at least partially cover side surfaces of a lower portion and a middle portion of the third conductive bump 360. A portion of an upper portion of the third conductive bump 360 may protrude from the filling support layer 370.

The adhesive layer 380 may be provided on the filling support layer 370 to at least partially cover a side surface of the upper portion of the third conductive bump 360 protruding from the filling support layer 370. For example, the adhesive layer 380 may include a non-conductive film (NCF).

The filling support layer 370 may have a first thickness, and the adhesive layer 380 may have a second thickness that is less than the first thickness. For example, the filling support layer 370 may have a thickness of 50% to 90% of a total thickness of the third conductive bump 360.

The fourth semiconductor chip 400 may be mounted on the third semiconductor chip 300 via fourth conductive bumps 460. The fourth semiconductor chip 400 may include a fourth substrate 410, an insulation interlayer and a first bonding pad 430. The fourth semiconductor chip 400 might not include a through silicon via, unlike the first to third semiconductor chips 100, 200, 300.

The fourth semiconductor chip 400 may be arranged on the third semiconductor chip 300 such that the first bonding pad 430 of the fourth semiconductor chip 400 faces toward the second bonding pad 350 of the third semiconductor chip 300.

The fourth conductive bump 460 may be interposed between the third semiconductor chip 300 and the fourth semiconductor chip 400. The fourth conductive bump 460 may electrically connect the second bonding pad 350 of the third semiconductor chip 300 and the first bonding pad 430 of the fourth semiconductor chip 400 to each other.

In exemplary embodiments of the present disclosure, a gap filling material layer having a double layer structure of different materials may be provided between the third semiconductor chip 300 and the fourth semiconductor chip 400. The gap filling material layer may be provided to completely fill spaces between neighboring bumps of the fourth conductive bumps 460. Alternatively, the gap filling material layer may partially till these spaces. The gap filling material layer may include a filling support layer 470 and an adhesive layer 480.

The filling support layer 470 may be coated on a front side of the fourth semiconductor chip 400 facing the third semiconductor chip 300 to at least partially cover side surfaces of a lower portion and a middle portion of the fourth conductive bump 360. A portion of an upper portion of the fourth conductive bump 460 may protrude from the tilling support layer 470.

The adhesive layer 480 may be provided on the filling support layer 470 to at least partially cover a side surface of the upper portion of the fourth conductive bump 460 protruding from the filling support layer 470. For example, the adhesive layer 480 may include a non-conductive film (NCF).

The filling support layer 470 may have a first thickness, and the adhesive layer 480 may have a second thickness that is less than the first thickness. The filling support layer 470 may have a thickness of 50% to 90% of a total thickness of the fourth conductive bump 460.

The molding member 600 may be provided on the package substrate 500 to at least partially cover the first to fourth semiconductor chips 100, 200, 300, 400. The molding member 600 may include an epoxy molding compound (EMC) material.

As mentioned above, the multi-chip package may include at least two first and second semiconductor chips 100, 200 stacked on the package substrate 500. The first semiconductor chip 100 may be mounted on the package substrate 500 via the first conductive bumps 160. The second semiconductor chip 200 may be mounted on the first semiconductor chip 100 via the second conductive bumps 260. The gap filling material layers having the double layer structure of different materials may be filled between the package substrate 500 and the first semiconductor chip 100 and between the first semiconductor chip 100 and the second semiconductor chip 200, respectively. The gap filling material layers may completely till the spaces between neighboring bumps of the first conductive bumps 160 and the spaces between neighboring bumps of the second conductive bumps 260 respectively. Alternatively, the gap filling material layer may partially fill these spaces. The gap filling material layers may include the tilling support layer 170, 270 and the adhesive layer 180, 280.

The tilling support layers 170, 270 may be provided on the front sides of the first and second semiconductor chips 100, 200 to fill the spaces between neighboring bumps of the first conductive bumps 160 and the spaces between neighboring bumps of the second conductive bumps 260, respectively. Accordingly, a backside of a wafer level chip may be grinded such that the first and second semiconductor chips 100, 200 are relatively thin. Further, as the first and second conductive bumps 160, 260 are relatively thin in height due to the filling support layers 170, 270, the gaps between the package substrate 500 and the first semiconductor chip 100 and between the first semiconductor chip 100 and the second semiconductor chip 200 may be reduced.

Thus, a thinner semiconductor package may be obtained.

Hereinafter, a method of manufacturing the semiconductor package in FIG. 1 will be explained.

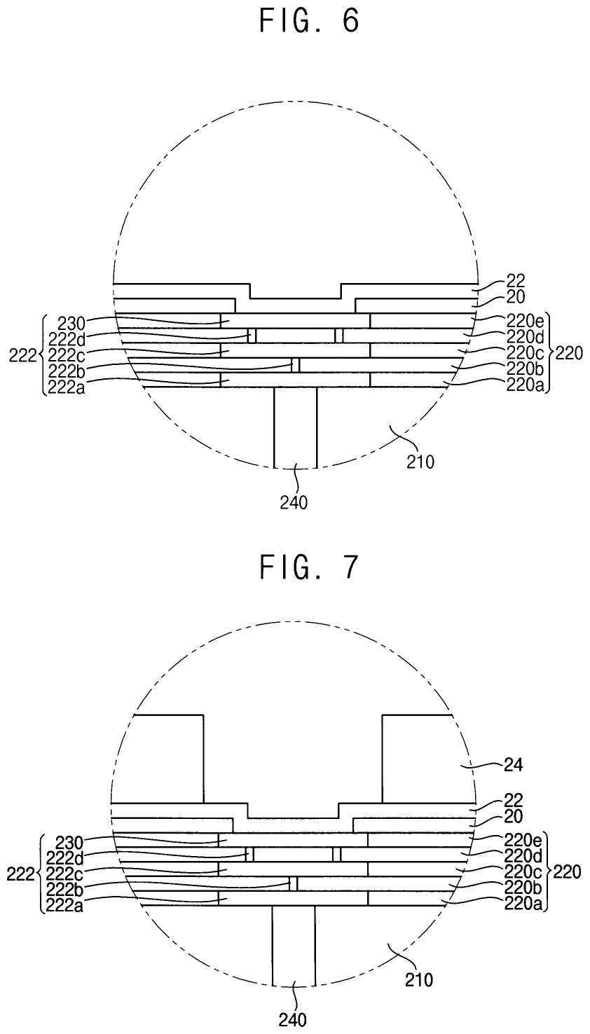

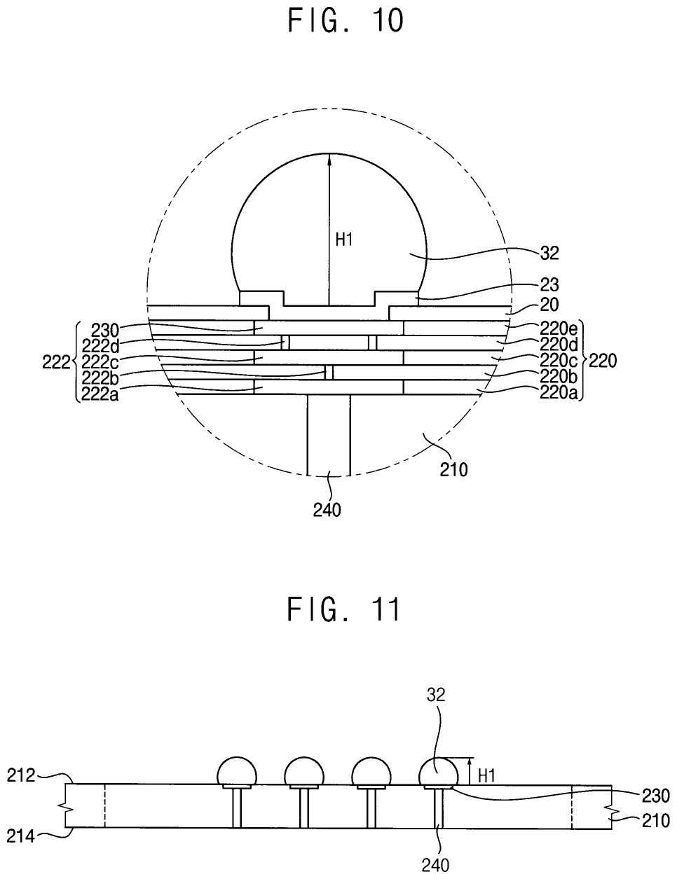

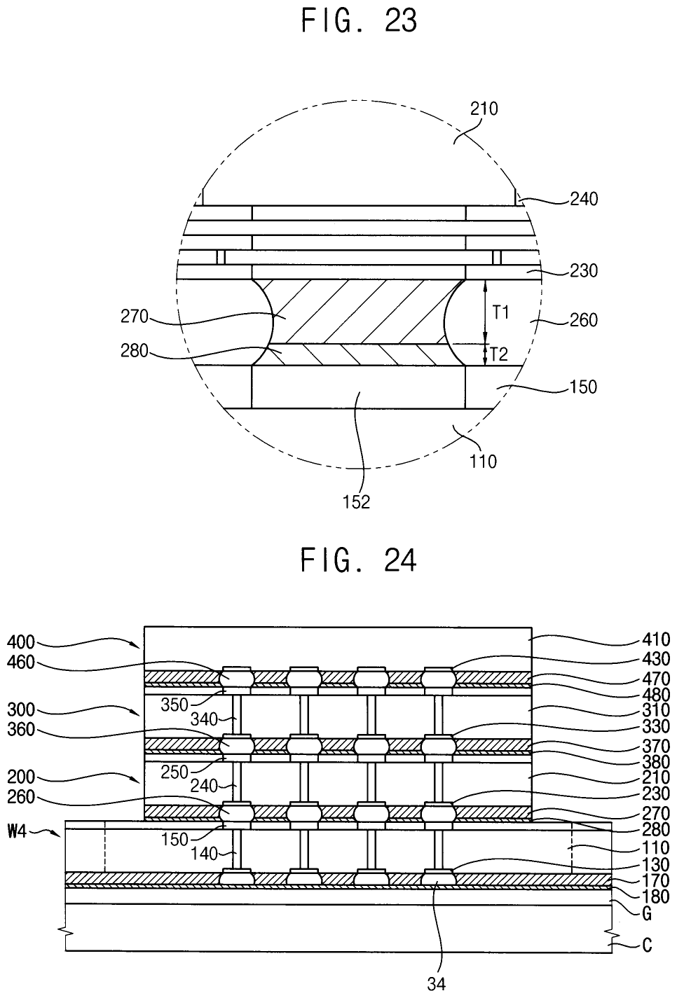

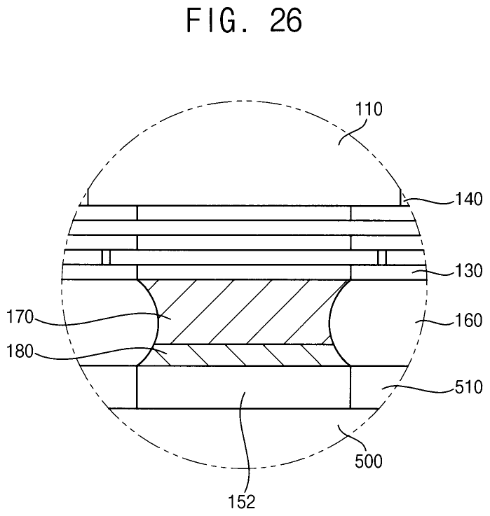

FIGS. 5 to 26 are cross-sectional views illustrating a method of manufacturing a semiconductor package according to exemplary embodiments of the present disclosure. FIGS. 6 to 10 are enlarged cross-sectional views illustrating portion D in FIG. 5. FIG. 23 is an enlarged cross-sectional view illustrating portion E in FIG. 22. FIG. 26 is an enlarged cross-sectional view illustrating portion F in FIG. 26.

Referring to FIGS. 5 to 11, first, bumps 32 may be formed on a first bonding pad 230 of a first wafer W1.

In exemplary embodiments of the present disclosure, the first wafer W1 may include a substrate 210, an insulation interlayer 220, the first bonding pad 230 and a through electrode 240. The insulation interlayer 220 may be provided on an active surface of the substrate 210. The first bonding pad 230 may be provided in an outermost insulation layer 220e of the insulation interlayer 220. The substrate 210 may include a die region DA where circuit patterns and cells are formed and a scribe lane region SA at least partially surrounding the die region DA. As will be described in greater detail later, the substrate 210 of the first wafer W1 may be sawed along the scribe lane region SA dividing a plurality of the die regions DA.

For example, the substrate 210 may include silicon, germanium, silicon-germanium, or III-V compounds, e.g., GaP, GaAs, GaSb, etc. some exemplary embodiments of the present disclosure, the substrate 210 may be a silicon-on-insulator (SOI) substrate, or a germanium-on-insulator (GOI) substrate.

Circuit patterns may be provided in/on the active surface of the substrate 210. The circuit patterns may include various circuit elements such as a transistor, a diode, etc.

The insulation interlayer 220 may be provided on the active surface of the substrate 210. The insulation interlayer 220 may include a plurality of insulation lavers 220a, 2′20.220c, 220d, 270e and a wiring 222 in the insulation layers. The wiring 222 may include a first metal wiring 222a, a first contact 222b, a second metal wiring 222d and a third metal wiring 230 respectively provided in the insulation layers 220a, 220b, 220c, 210d, 220e. At least a portion of the third metal wiring 230 may serve as the first bonding pad as a landing pad. The first bonding pad 230 may be provided in a front side of the first wafer W1, which is, hereinafter, referred to as a first surface 212 of the substrate 210 for simplicity of explanation.

The through electrode 240 may be provided to penetrate through the substrate 210. The through electrode 240 may be electrically connected to the first bonding pad 230 through the wiring 222 of the insulation interlayer 220. The through electrode 240 may be formed before grinding a backside of the substrate 210, for example, a second surface 214 as illustrated in FIG. 16 (via first process, via middle process). Alternatively, the through electrode may be formed after grinding the backside of the substrate 210 as illustrated in FIG. 16 (via last process).

In exemplary embodiments of the present disclosure, the bumps 32 may be formed on the first bonding pad 230.

As illustrated in FIG. 6, an insulation layer pattern 20 may be formed on the first surface 212 of the substrate 210 to expose the first bonding pad 230, and thereafter, a seed layer 22 may be formed on die first bonding pad 230.

For example, the insulation layer pattern 20 may include oxide, nitride, etc. These may be used alone or in a mixture thereof. Additionally, the insulation layer pattern 20 may be formed by a chemical vapor deposition (CVD) process, a plasma enhanced chemical vapor deposition (PECVD) process, an atomic layer deposition (ALD) process, a lower pressure chemical vapor deposition (LPCVD) process, a sputtering process, etc. Alternatively, the insulation layer pattern 20 may include a polymer layer formed by a spin coating process or a spray process. In case that a protective layer pattern for exposing the first bonding pad 230 is formed on the first surface 212 of the substrate 210, the process of forming the insulation layer pattern may be omitted.

The seed layer 22 may include an alloy layer including titanium/copper (Ti/Cu), titanium/palladium (Ti/Pd), titanium/nickel (Ti/Ni), chrome/copper (Cr/Cu) or a combination thereof.

Then, as illustrated in FIG. 7, a photoresist pattern 24 may be formed on the first surface 212 of the substrate 210 to have an opening which at least partially exposes a region of the seed layer 22.

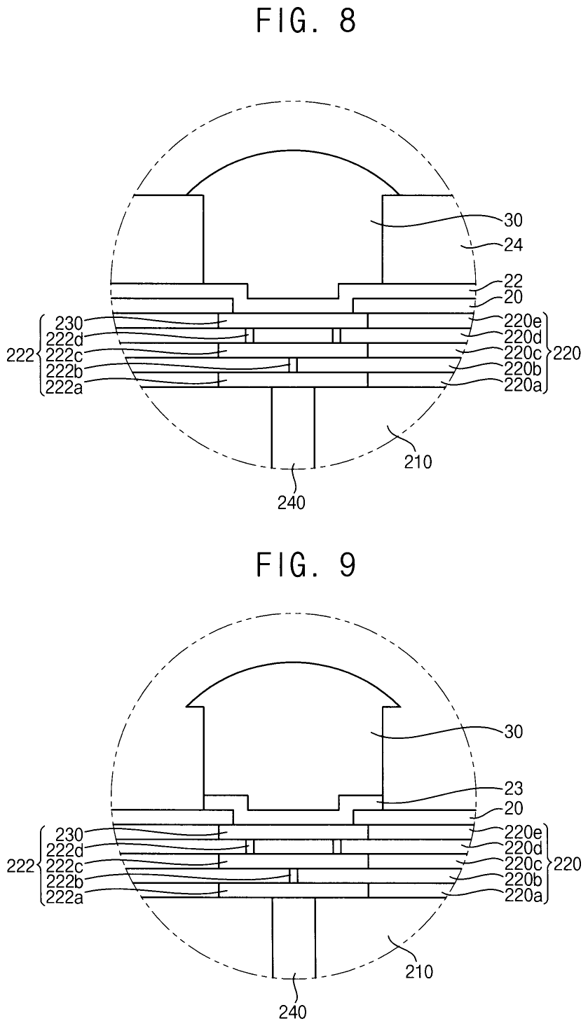

As illustrated in FIGS. 8 to 10, the bump 32 may be formed on the first bonding pad 230 of the substrate 210.

In particular, a conductive material 30 may be formed to fill the opening of the photoresist pattern 24, the photoresist pattern 24 may be removed, and then, a reflow process may be performed to form the bump 32. For example, the conductive material 30 may be formed on the seed layer 22 by an electroplating process. Alternatively, the bump 32 may be formed by a screen printing process, a deposition process, etc.

The bump 32 may have a first height H1 from the first surface 212 of the substrate 210. For example, the first height H1 of the bump 32 may range from 50 μm to 150 μm.

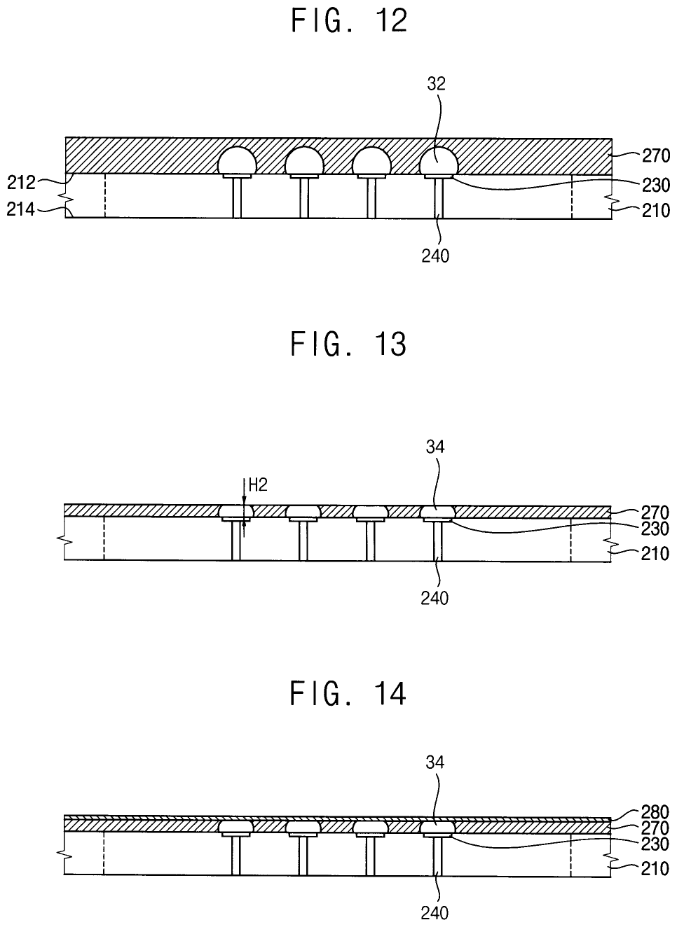

Referring to FIGS. 12 to 17, a filling support layer 270 may be formed on the first surface 212 of the substrate 210, and then, the backside of the substrate 210, for example, the second surface 214 may be grinded.

As illustrated in FIGS. 12 and 13, after the filling support layer 270 is formed on the first surface 212 of the substrate 210 to at least partially cover the bump 32, an upper surface of the filling support layer 270 may be removed to expose the bump 32.

Then, an upper portion of the filling support layer 270 may be removed to expose the bump 32. A portion of the filling support layer 270 may be removed by a grinding process, an etch process, etc. Here, the upper portion of the filling support layer 270 may be removed to form a second bump 34. Accordingly, a height H2 of the second bump 34 may be less than the height H1 of the bump 32. Thus, as the height of the bump is reduced, a gap between a semiconductor chip and a wafer or between a semiconductor chip and a semiconductor chip to thereby obtain a relatively thin package.

The filling support layer 270 may be formed on the first surface 212 of the substrate 210 to completely fill spaces between neighboring bumps of the bumps 32. Alternatively, the filling support layer 270 may partially fill these spaces. The filling support layer 270 may include an insulation material capable of preventing warpage of the wafer during a wafer backside grinding process.

Then, as illustrated in FIG. 14, an adhesive layer 280 may be formed on the filling support layer 280 on the first surface 212 of the substrate 210.

For example, the adhesive layer 280 may include a non-conductive film (NCF). Accordingly, the adhesive layer may be used while the substrate 210 that is divided individually from the first wafer W1 is adhered on another wafer or a semiconductor chip with the bump interposed therebetween. Accordingly, the adhesive layer may be formed on the filling support layer 270 before the substrate is adhered on another wafer (or semiconductor chip) as illustrated in FIG. 22.

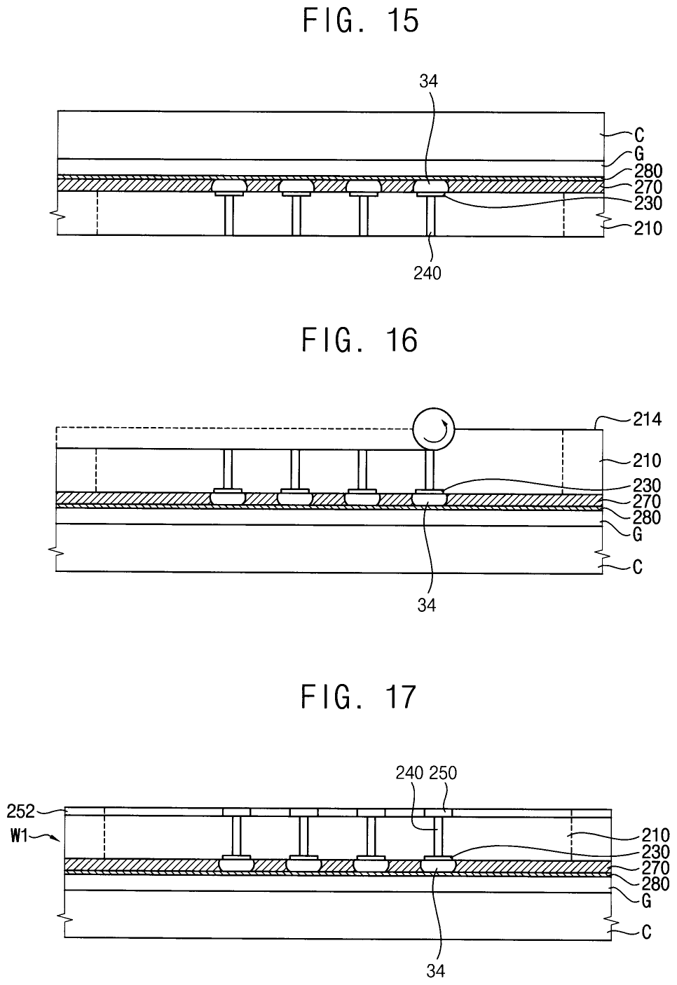

Then, as illustrated in FIGS. 15 and 16, the backside of the substrate 210, for example, the second surface 214 may be grinded using a substrate support system WSS. After the first wafer W1 is arranged on a carrier substrate C, the second surface 214 of the substrate 210 may be grinded. The filling support layer 270 on the first surface 212 of the substrate 210 may be adhered on a bonding layer G on the carrier substrate C.

The second surface 214 of the substrate 210 may be grinded by a grinding process. Here, the substrate 210 may be grinded relatively thin by the filling support layer 270 which may completely fill the spaces between neighboring bumps of the second bumps 34. For example, the filling grinding layer 270 may prevent warpage of the first wafer W1 during the grinding process, and thus, the backside of the substrate 210 may be grinded relatively thin using the substrate support system under the same condition.

Referring to FIG. 17, a second bonding pad 250 may be formed on the second surface 214 of the substrate 210.

An insulation layer 252 having the second bonding pad 250 may be formed on the second surface 214 of the substrate 210. The second bonding pad 250 may be formed on an end portion of the through electrode 240.

Where the through electrode is formed by the via last process, the step of forming the second bonding pad may be performed when or after the through electrode is formed.

Referring to FIG. 18, the carrier substrate C may be removed from the substrate 210, and the first wafer W1 may be sawed along the scribe lane region SA such that the substrate 210 may be divided into an individual second semiconductor chip.

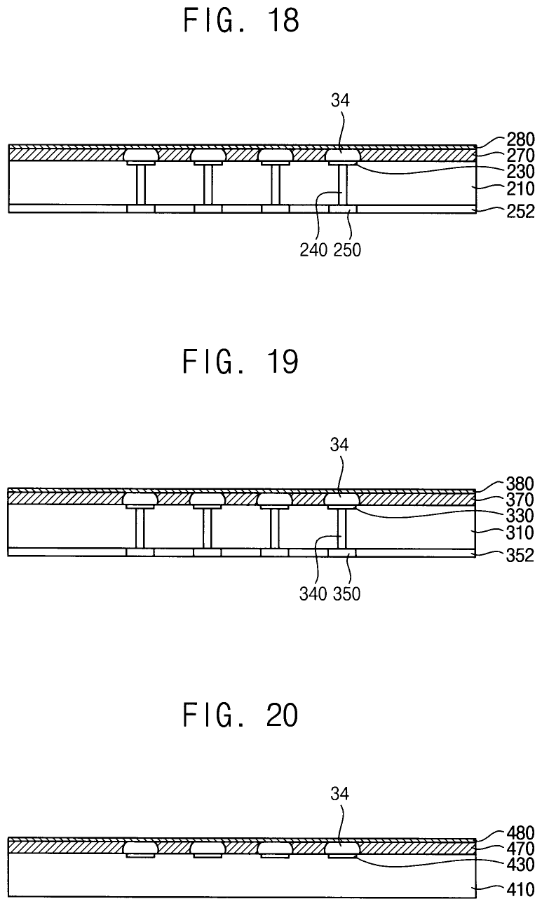

Referring to FIG. 19, processes that is the same as or similar to the processes described with reference to FIGS. 5 to 18 may be performed on a second wafer to form an individual third semiconductor chip 300.

The third semiconductor chip 300 may include a substrate 310, a first bonding pad 330 and a second bonding pad 350 respectively provided on a first surface and a second surface of the substrate 310. A through electrode 340 penetrates through the substrate 310. Second bumps 34 are provided on the first bonding pad 330 on the substrate 310. A filling support layer 370 fills spaces between neighboring bumps of the bumps 34 on the first surface of the substrate 310. An adhesive layer 380 is disposed on the filling support layer 370.

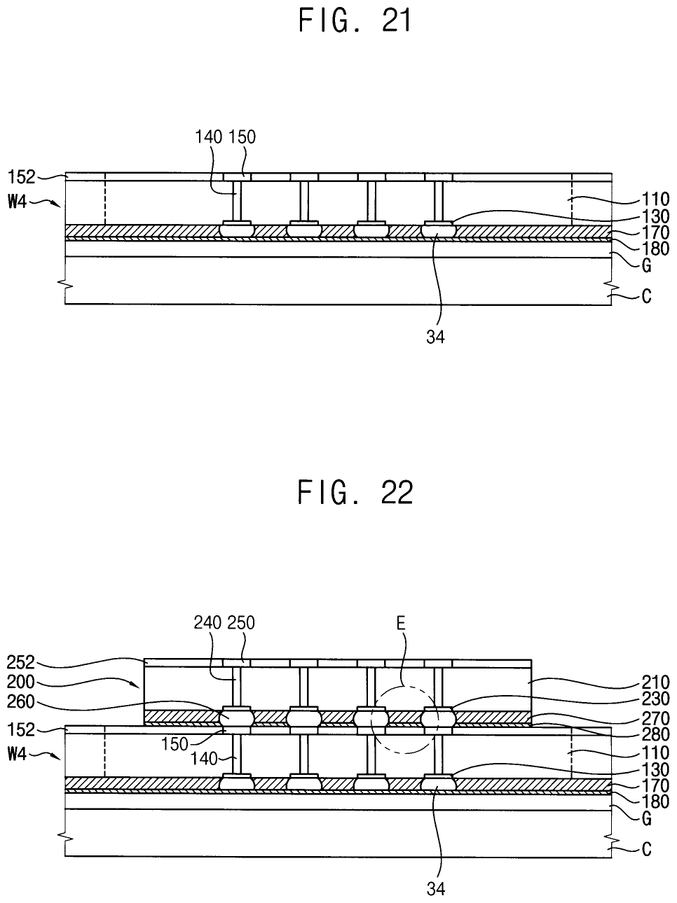

Referring to FIG. 20, processes the same as or similar to the processes described with reference to FIGS. 5 to 18 may be performed on a third wafer to form an individual fourth semiconductor chip 400.

The fourth semiconductor chip 400 may include a substrate 410. A first bonding pad 430 is provided on a first surface of the substrate 410. Second bumps 34 are provided on the first bonding pad 430 on the substrate 410. A filling support layer 470 fills spaces between neighboring bumps of the bumps 34 on the first surface of the substrate 410. An adhesive layer 480 is disposed on the filling support layer 470. The fourth semiconductor chip 400 might not include a through silicon via.

Referring to FIG. 21, processes the same as or similar to the processes described with reference to FIGS. 5 to 17 may be performed on a fourth wafer to form a filling support layer 170 filling spaces between neighboring second bumps 34 on a first surface of a substrate 110, to grind a second surface of the substrate 110 and to form a second bonding pad 150.

Referring to FIGS. 22 and 23, the second semiconductor chip may be stacked on the substrate 110 of the fourth wafer W4.

In exemplary embodiments of the present disclosure, the second semiconductor chip may be adhered on the fourth wafer W4 using the adhesive layer 280 such as the non-conductive film. For example, after the fourth wafer W4 is arranged on a stage of a chip bonding apparatus, the second semiconductor chip may be adsorbed on a head of the chip bonding apparatus, and then, may be thermal-compressed onto the fourth wafer W4.

As illustrated in FIG. 23, the adhesive layer 280 may be heated and the second bump may be reflowed to form a (second) conductive bump 260 between the second bonding pad 150 of the substrate 110 and the first bonding pad 230 of the second semiconductor chip. Here, the filling support layer 270 may be formed on the front side of the substrate 210 of the second semiconductor chip, and the adhesive layer 280 may be formed on the filling support layer 270.

The filling support layer 270 may be coated on the front side of the second semiconductor chip 200 facing the substrate 110 of a first semiconductor chip 100 to at least partially cover side surfaces of the (second) conductive bumps 260. The filling support layer 270 may cover side surfaces of a lower portion and a middle portion of the (second) conductive bump 260. An upper portion of the (second) conductive bump 260 may protrude from the filling support layer 270.

The adhesive layer 280 may fill spaces between neighboring bumps of the (second) conductive bumps 260 on the filling support layer 270. The adhesive layer 280 may cover a side surface of the upper portion of the (second) conductive bump 260 protruding from the tilling support layer 270.

The filling support layer 270 may have a first thickness T1, and the adhesive layer 280 may have a second thickness T2 that is less than the first thickness T1. The filling support layer 270 may have a thickness of 50% to 90% of a total thickness of the (second) conductive bump 260.

Referring to FIG. 24, processes the same as or similar to the processes described with reference to FIGS. 22 and 23 may be performed to stack the third semiconductor chip on the second semiconductor chip and stack the fourth semiconductor chip 400 on the third semiconductor chip 300.

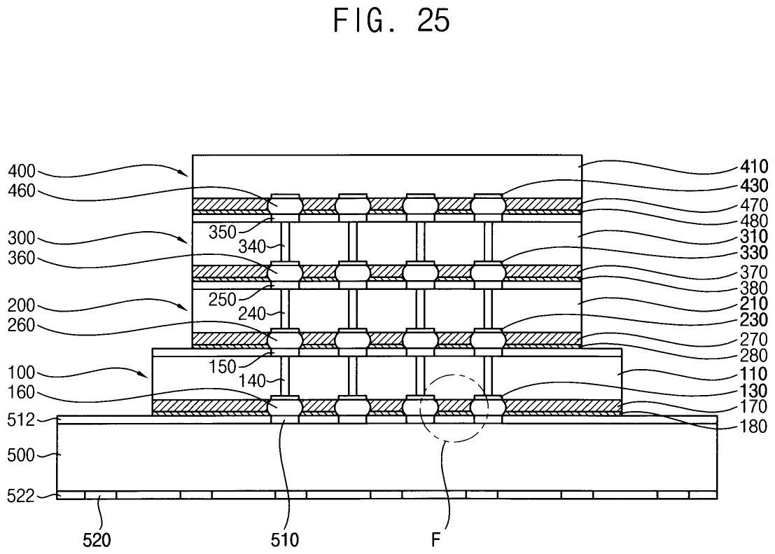

Referring FIGS. 25 and 26, the fourth wafer (W4) may be sawed and a stacked structure (stacked first to fourth semiconductor chips) may be mounted on a package substrate 500. Processes the same as or similar to the processes described with reference to FIGS. 22 and 23 may be performed to stack the first semiconductor chip on a package substrate 500.

In exemplary embodiments of the present disclosure, the first semiconductor chip may be adhered on the package substrate 500 using the adhesive layer 180 such as the non-conductive film. For example, after the package substrate 500 is arranged on a stage of a chip bonding apparatus, the stacked structure including the first semiconductor chip may be adsorbed on a head of the chip bonding apparatus, and then, may be thermal-compressed onto the package substrate 500.

As illustrated in FIG. 26, the adhesive layer 180 may be heated and the second bump may be reflowed to form a conductive bump 160 between a bonding pad 510 of the package substrate 500 and the first bonding pad 130 of the first semiconductor chip. Here, the filling support layer 170 may be formed on the front side of the substrate 110 of the first semiconductor chip, and die adhesive layer 180 may be formed on the filling support layer 170. The filling support layer 170 may till spaces between neighboring conductive bumps 160. A thickness of the filling support layer 170 may be greater than a thickness of the adhesive layer 180.

Then, a molding member may be formed on an upper surface of the package substrate 500 to at least partially cover the first to fourth semiconductor chips 100, 200, 300, 400, and then, outer connection members may be disposed on outer connection pads 520 on a lower surface of the package substrate 500 to complete the semiconductor package 10 in FIG. 1.

Hereinafter, a thickness of a stacked semiconductor chip, according to a comparative embodiment, and a thickness of a stacked semiconductor chip, according to an exemplary embodiment of the present disclosure, will be explained.

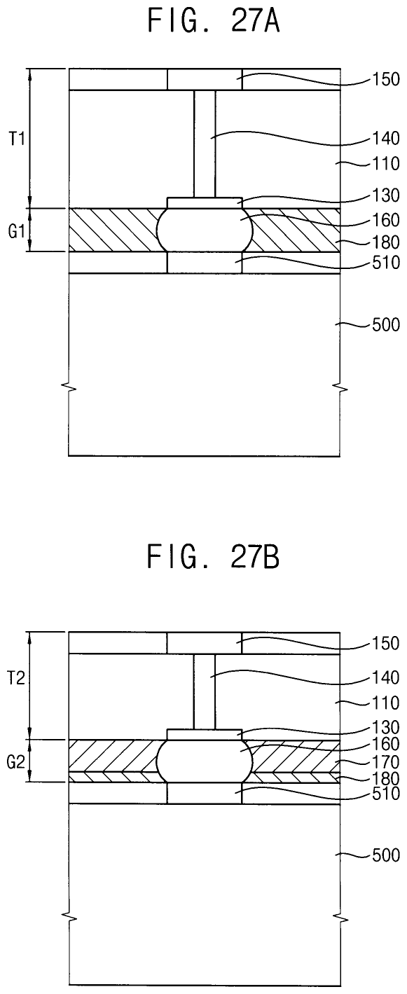

FIG. 27A is a cross-sectional view illustrating a first semiconductor chip stacked on a mounting substrate in accordance with a comparative embodiment, and FIG. 27B is a cross-sectional view illustrating a first semiconductor chip stacked on a mounting substrate in accordance with exemplary embodiments of the present disclosure.

Referring to FIG. 27A processes the same as or similar to the processes described with reference to FIGS. 5 to 11 may be performed to form bumps on a first bonding pad 130 on a front side of a first substrate 110, and to grind a backside, for example, second surface of the first substrate 110 using a substrate support system (WSS). The grinding process may be performed while the front side of the first substrate 110 is adhered on a carrier substrate.

Then, the bump may be reflowed by a chip bonding process using a non-conductive film 180 to form a conductive bump 160 between a bonding pad 510 of a package substrate 500 and the first bonding pad 130 of the first substrate 110.

In this case, the first substrate 110 may have a first thickness T1, and the package substrate 500 and the first semiconductor chip may be spaced apart from each other by a first gap G1.

Referring to FIG. 27B, processes the same as or similar to the processes described with reference to FIGS. 5 to 11 may be performed to form bumps on a first bonding pad 130 on a front side of a first substrate 110, and processes the same as or similar to the processes described with reference to FIGS. 12 to 16 may be performed to form a filling support layer 170 on the front side of the first substrate 110 and to grind a backside, for example, second surface of the first substrate 110.

The grinding process may be performed on the second surface of the first substrate 110 including the filling support layer 170 formed on the front side of the first substrate 110. Here, the filling support layer 170 may completely fill spaces between neighboring bumps to support the front side of the first substrate 110, and accordingly, the substrate 110 may be grinded relatively thin. For example, the filling grinding layer 170 may prevent warpage of the wafer during the grinding process, and thus, the backside of the substrate 110 may be grinded relatively thin using the substrate support system under the same condition.

Then, the bump may be reflowed by a chip bonding process using a non-conductive film 180 to form a conductive bump 160 between a bonding pad 510 of a package substrate 500 and the first bonding pad 130 of the first substrate 110.

In this case, the first substrate 110 may have a second thickness T2 that is less than the first thickness T1, and the package substrate 500 and the first semiconductor chip may be spaced apart from each other by a second gap G2 that is less that the first gap G1.

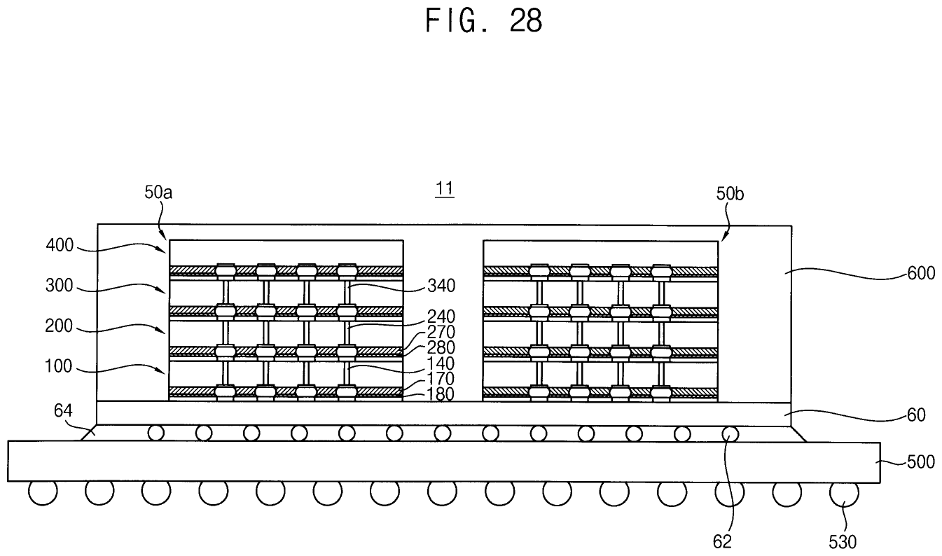

FIG. 28 is a cross-sectional view illustrating a semiconductor package in accordance with exemplary embodiments of the present disclosure. The semiconductor package may be substantially the same as or similar to the semiconductor package described with reference to FIG. 1 except for configuration of semiconductor devices. Thus, same reference numerals may be used to refer to the same or like elements and to the extent that a detailed description of some elements is omitted, it may be assumed that these elements are at least similar to corresponding elements that have been described elsewhere in the specification.

Referring to FIG. 28, a semiconductor package 11 may include a package substrate 500, a first semiconductor device 60, at least one second semiconductor device 50a, 50b and a molding member 600. Additionally, the semiconductor package 11 may further include outer connection members 530.

In exemplary embodiments of the present disclosure, the semiconductor package 11 may be an electronic device such as System In Package (SIP). The first semiconductor device 60 may be an interposer, and the second semiconductor device 50a, 50b may include HBM (High Bandwidth Memory) device. Alternatively, the first semiconductor device 60 may include a first electronic product such as logic semiconductor device, and the second semiconductor device 50a, 50b may include a second electronic product such as memory device.

As illustrated in FIG. 28, the second semiconductor device 50a, 50b may include first to fourth semiconductor chips 100, 200, 300, 400 stacked on one another as illustrated in FIG. 1. The first to fourth semiconductor chips 100, 200, 300, 400 may be electrically connected to each other by through electrodes 140, 240, 340 such as through silicon vias (TSVs).

The first semiconductor chip 100 may be mounted on the first semiconductor device 60 via first conductive bumps. The second semiconductor chip 200 may be mounted on the first semiconductor 100 by second conductive bumps. Gap filling material layers having a double layer structure of different materials may be filled between the first semiconductor device 60 and the first semiconductor chip 100 and between the first semiconductor chip 100 and the second semiconductor chip 200 respectively. The gap filling material layers may be provided to completely fill gaps between each of the first conductive bumps and gaps between each of the second conductive bumps, respectively. Alternatively, the gap filling material layer may partially fill these gaps. The gap filling material layer may include a filling support layer 170, 270 and an adhesive layer 80, 280.

The filling support layers 170, 270 may be provided on the front sides of the first and second semiconductor chips 100, 200 to fill the spaces between neighboring first conductive bumps 160 and the spaces between neighboring second conductive bumps 260, respectively, and accordingly, a backside of a wafer level chip may be grinded such that the first and second semiconductor chips 100, 200 are relatively thin. Further, as the first and second conductive bumps 160, 260 are relatively thin in height due to the filling support layers 170, 270, the gaps between the first semiconductor device 60 and the first semiconductor chip 100 and between the first semiconductor chip 100 and the second semiconductor chip 200 may be reduced.

Thus, a relatively thin semiconductor package may be obtained.

The semiconductor package may be applied for various systems such as a computing system. The semiconductor device may include fin FET, DRAM, VNAND, etc. The semiconductor package may include logic devices such as central processing units (CPUs), main processing units (MPUs), or application processors (APs), or the like, and volatile memory devices such as DRAM devices, SRAM devices, non-volatile memory devices such as flash memory devices, PRAM devices, MRAM devices, ReRAM devices, or CMOS image sensor (CIS).

The foregoing is illustrative of exemplary embodiments of the present disclosure, and is not to be construed as limiting thereof. Although a few exemplary embodiments of the present disclosure have been described herein, those skilled in the art will readily appreciate that many modifications are possible in example embodiments without materially departing from the novel teachings and aspects of the present invention.

1. A semiconductor package, comprising:
a first semiconductor chip including a first through electrode;
a second semiconductor chip, stacked on the first semiconductor chip, and including a second through electrode;
a plurality of conductive bumps interposed between the first semiconductor chip and the second semiconductor chip, the plurality of conductive bumps electrically connecting the first and second through electrodes to each other;
a filling support layer at least partially covering a first surface of the second semiconductor chip that faces the first semiconductor chip and at least partially filling spaces between neighboring conductive bumps of the plurality of conductive bumps; and
an adhesive layer disposed on the filling support layer and at least partially filling the spaces between neighboring conductive bumps of the plurality of conductive bumps and adhering the first and second semiconductor chips to each other.

2. The semiconductor package of claim 1, wherein the filling support layer at least partially covers side surfaces of a lower portion and a middle portion of each conductive bump of the plurality of conductive bumps, and the adhesive layer at least partially covers a side surface of an upper portion of each conductive bump of the plurality of conductive bumps protruding from the filling support layer.

3. The semiconductor package of claim 1, wherein the filling support layer has a first thickness, and the adhesive layer has a second thickness that is less than the first thickness.

4. The semiconductor package of claim 1, wherein the filling support layer comprises an epoxy, and the adhesive layer comprises a non-conductive film.

5. The semiconductor package of claim 1, wherein the second semiconductor chip includes a first bonding pad on the first surface and a second bonding pad on a second surface that is opposite to the first surface, and each conductive bump of the plurality of conductive bumps is disposed on the first bonding pad.

6. The semiconductor package of claim 5, wherein the first bonding pad and the second bonding pad are electrically connected to each other by the second through electrode.

7. The semiconductor package of claim 1, wherein the second semiconductor chip further include an insulation interlayer, the insulation interlayer including a first bonding pad in an outer surface thereof.

8. The semiconductor package of claim 1, further comprising a package substrate,
wherein the first semiconductor chip is mounted on the package substrate, via second conductive bumps.

9. The semiconductor package of claim 8, further comprising:
a second filling support layer at least partially covering a third surface of the first semiconductor chip facing the package substrate and at least partially filling spaces between neighboring bumps of the second conductive bumps; and
a second adhesive layer disposed on the second filling support layer and at least partially filling the spaces between neighboring bumps of the second conductive bumps and adhering the first semiconductor chip and the package substrate to each other.

10. The semiconductor package of claim 9, wherein the first semiconductor chip includes a third bonding pad disposed on the third surface and a forth bonding pad disposed on a fourth surface opposite to the third surface, and the second conductive bump is disposed on the third bonding pad.

11. A semiconductor package, comprising:
a first semiconductor chip including a first substrate including a first surface and a second surface opposite to the first surface, a first bonding pad disposed on the first surface, and a first through electrode penetrating through the first substrate and electrically connected to the first bonding pad;
a second semiconductor chip stacked on the second surface of the first semiconductor chip the second semiconductor chip including a second substrate including a third surface and a fourth surface opposite to the third surface, a third bonding pad disposed on the third surface, and a second through electrode penetrating through the second substrate and electrically connected to the third bonding pad;
a plurality of conductive bumps interposed between the first semiconductor chip and the second semiconductor chip and electrically connecting the first and second through electrodes to each other; and
a gap filling material layer disposed between the first semiconductor chip and the second semiconductor chip and at least partially filling spaces between neighboring conductive bumps of the plurality of conductive bumps, and including a filling support layer, including a first material, at least partially covering a front side of the second semiconductor chip facing the first semiconductor chip and an adhesive layer, including a second material, adhering on the filling support layer.

12. The semiconductor package of claim 11, wherein the filling support layer at least partially covers side surfaces of a lower portion and a middle portion of each conductive bump of the plurality of conductive bumps, and the adhesive layer covers a side surface of an upper portion, of each conductive bump of the plurality of conductive bumps, protruding from the filling support layer.

13. The semiconductor package of claim 11, wherein the filling support layer has a first thickness, and the adhesive layer has a second thickness that is less than the first thickness.

14. The semiconductor package of claim 11, wherein the filling support layer comprises an epoxy material, and the adhesive layer comprises a non-conductive film.

15. The semiconductor package of claim 11, wherein the first semiconductor chip includes a second bonding pad disposed on the second surface, and each conductive bump of the plurality of conductive bumps is disposed between the second bonding pad and the third bonding pad.

16. The semiconductor package of claim 11, wherein the second semiconductor chip includes a fourth bonding pad on the fourth surface, and the third bonding pad and the fourth bonding pad are electrically connected to each other by the second through electrode.

17. The semiconductor package of claim 11, wherein the second semiconductor chip further include an insulation interlayer, the insulation interlayer including the third bonding pad in an outer surface thereof.

18. The semiconductor package of claim 11, further comprising a package substrate,
wherein the first semiconductor chip is mounted on the package substrate via a plurality of second conductive bumps.

19. The semiconductor package of claim 18, further comprising:
a filling support layer at least partially covering a front side of the first semiconductor chip facing the package substrate and at least partially filling spaces between neighboring conductive bumps of the plurality of second conductive bumps; and
an adhesive layer disposed on the filling support layer and at least partially filling the spaces between neighboring conductive bumps of the plurality of second conductive bumps and adhering the first semiconductor chip and the package substrate to each other.

20. (canceled)

21. A semiconductor package, comprising:
a package substrate;
a first semiconductor chip stacked on the package substrate, the first semiconductor chip including a first substrate including a first surface and a second surface opposite to the first surface, first bonding pads on the first surface, and a first through electrode penetrating through the first substrate and electrically connected to the first bonding pad;
a plurality of conductive bumps arranged between substrate pads of the package substrate and the first bonding pads of the first semiconductor chip, respectively;
a filling support layer coated on the first surface of the first semiconductor chip and at least partially covering a side surface of each conductive bump of the plurality of conductive bumps; and
an adhesive layer disposed on the filling support layer and at least partially covering the side surface of each conductive bump of the plurality of conductive bumps and adhering the package substrate and the first semiconductor chip to each other.

22-40. (canceled)
